(19) United States
(12) Patent Application Publication
(10) Pub. No.: US 2003/0071323 A1
(43) Pub. Date: Apr. 17, 2003

(54) Microelectronic fabrication with upper lying aluminum fuse layer in copper interconnect semiconductor technology and method for fabrication thereof

(75) Inventors: Kuo-Yu Chou, Hsin-Chu (TW); Tong-Chern Ong, Junghe City (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 09/978,420

(22) Filed: Oct. 15, 2001

(51) Int. Cl. H01L 29/00

(52) U.S. Cl. 257/529; 257/516; 257/741; 257/762; 257/797

(57) ABSTRACT

Within both a microelectronic fabrication and a method for fabricating the microelectronic fabrication, there is employed at least one fuse layer electrically connected with a series of patterned conductor layers separated by a series of dielectric layers, where the at least one fuse layer is formed at a level no lower than a highest of the series of patterned conductor layers within the microelectronic fabrication. When formed within the context of the foregoing constraint, there is provided enhanced access for actuation of the at least one fuse layer within the microelectronic fabrication.

### BACKGROUND OF THE INVENTION

1. Field of the Invention

The present invention relates generally to methods for fabricating microelectronic fabrications. More particularly, the present invention relates to methods for fabricating, with enhanced efficiency, microelectronic fabrications.

2. Description of the Related Art

Microelectronic fabrications are formed from microelectronic substrates over which are formed patterned microelectronic conductor layers which are separated by microelectronic dielectric layers.

As microelectronic fabrication integration levels have increased and microelectronic device and patterned microelectronic conductor layer dimensions have decreased, it has become increasingly common in the art of microelectronic fabrication, and in particular in the art of semiconductor integrated circuit microelectronic memory fabrication, to employ when fabricating microelectronic fabrications, and in particular when fabricating semiconductor integrated circuit microelectronic memory fabrications, fuse layers. Fuse layers in turn may be employed for purposes of severing from within a microelectronic fabrication non-functional portions of the microelectronic fabrication, such as but not limited to a block of non-functional memory cells within a semiconductor integrated circuit microelectronic memory fabrication, while providing for connection of redundant circuitry portions of the microelectronic fabrication, to provide an operational microelectronic fabrication from an otherwise non-operational microelectronic fabrication.

While fuse layers are thus clearly desirable in the art of microelectronic fabrication for fabricating microelectronic fabrications, and often unavoidable in the art of microelectronic fabrication for fabricating microelectronic fabrications, fuse layers are nonetheless not entirely without problems in the art of microelectronic fabrication for fabricating microelectronic fabrications.

In that regard, insofar as fuse layers within microelectronic fabrications are typically formed at earlier stages in fabrication of microelectronic fabrications, fuse layers often present difficulties in their access and actuation within microelectronic fabrications. Such difficulties in access and actuation of fuse layers is often particularly acute within an embedded memory semiconductor integrated circuit microelectronic memory fabrications where memory portions of the embedded memory semiconductor integrated circuit microelectronic memory fabrication are generally fabricated employing fewer conductor layers than logic portions within the embedded memory semiconductor integrated circuit microelectronic fabrication.

It is thus desirable in the art of microelectronic fabrication to provide microelectronic fabrications, and methods for fabrication thereof, wherein fuse layers are more readily accessed and actuated.

It is towards the foregoing object that the present invention is directed.

Various microelectronic fabrications having formed therein fuse layers with desirable properties, and methods for fabrication thereof, have been disclosed in the art of microelectronic fabrication.

Included among the microelectronic fabrications and methods for fabrication thereof, but not limited among the microelectronic fabrications and methods for fabrication thereof are microelectronic fabrications and methods for fabrication thereof disclosed within: (1) Rodriguez et al., in U.S. Pat. No. 5,821,160 (a semiconductor integrated circuit microelectronic memory fabrication, and method for fabrication thereof, which employ an etch stop layer for purposes of uniformly etching through a series of dielectric layers formed thereover within the semiconductor integrated circuit microelectronic fabrication without overetching into a fuse layer formed thereunder within the semiconductor integrated circuit microelectronic fabrication when etching through the series of dielectric layers and the etch stop layer within the semiconductor integrated circuit microelectronic fabrication to access and actuate the fuse layer within the semiconductor integrated circuit microelectronic fabrication); and (2) Hsiao et al., in U.S. Pat. No. 5,985,765 (a microelectronic fabrication, and method for fabrication thereof, which employ a capping layer formed upon a bond pad layer such as to avoid over-etching into the bond pad layer when simultaneously etching within the microelectronic fabrication a comparatively shallow first via to access the bond pad layer within the microelectronic fabrication and a comparatively deep second via to access and actuate a fuse layer within the microelectronic fabrication).

Desirable in the art of microelectronic fabrication, and particularly in the art of semiconductor integrated circuit microelectronic fabrication, and more particularly in the art of semiconductor integrated circuit microelectronic memory fabrication, are additional microelectronic fabrications, and methods for fabrication thereof, which provide for enhanced access and actuation of fuse layers within microelectronic fabrications.

It is towards the foregoing object that the present invention is directed.

### SUMMARY OF THE INVENTION

A first object of the present invention is to provide a microelectronic fabrication, and a method for fabricating the microelectronic fabrication.

A second object of the present invention is to provide the microelectronic fabrication and the method for fabricating the microelectronic fabrication in accord with the first object of the present invention, wherein there is provided for enhanced access and actuation of a fuse layer within the microelectronic fabrication.

A third object of the present invention is to provide a method in accord with the first object of the present invention and the second object of the present invention, wherein the method is readily commercially implemented.

In accord with the objects of the present invention, there is provided by the present invention a microelectronic fabrication and a method for fabricating the microelectronic fabrication.

To practice the method of the present invention, there is first provided a substrate. There is then formed over the substrate a series of patterned conductor layers separated by a series of dielectric layers. Finally, there is then formed over the substrate and electrically connected with the series of patterned conductor layers separated by the series of dielectric layers at least one fuse layer, wherein the at least one fuse layer is formed at a level no lower than a highest of the series of patterned conductor layers.

The method for fabricating the microelectronic fabrication in accord with the present invention contemplates a microelectronic fabrication fabricated in accord with the method for fabricating the microelectronic fabrication in accord with the present invention.

The present invention provides a microelectronic fabrication, and a method for fabricating the microelectronic fabrication, wherein there is provided for enhanced access and actuation of a fuse layer within the microelectronic fabrication.

The present invention realizes the foregoing object by forming, when fabricating a microelectronic fabrication, a fuse layer at a level no lower than a highest of a series of patterned conductor layers within the microelectronic fabrication. By forming within the microelectronic fabrication in accord with the present invention the fuse layer at the level no lower than the highest of the series of patterned conductor layers within the microelectronic fabrication, the fuse layer is provided with enhanced access and actuation.

The method of the present invention is readily commercially implemented.

As is illustrated in greater detail within the context of the Description of the Preferred Embodiment, as set forth below, a microelectronic fabrication fabricated in accord with the present invention may be fabricated employing methods and materials as are otherwise generally conventional in the art of microelectronic fabrication, but employed within the context of specific process limitations and specific structural limitations to provide a microelectronic fabrication in accord with the present invention. Since it is thus at least in part a series of process limitations and structural limitations which provides at least in part the present invention, rather than the existence of methods and materials which provides the present invention, the method of the present invention is readily commercially implemented.

### BRIEF DESCRIPTION OF THE DRAWINGS

The objects, features and advantages of the present invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3 and FIG. 4 show a series of schematic cross-sectional diagrams illustrating the results of progressive stages of fabricating a microelectronic fabrication in accord with a preferred embodiment of the present invention.

### DESCRIPTION OF THE PREFERRED EMBODIMENT

The present invention provides a microelectronic fabrication, and a method for fabricating the microelectronic fabrication, wherein there is provided for enhanced access and actuation of a fuse layer within the microelectronic fabrication.

The present invention realizes the foregoing object by forming, when fabricating a microelectronic fabrication, a fuse layer at a level no lower than a highest of a series of patterned conductor layers within the microelectronic fabrication. By forming within the microelectronic fabrication in accord with the present invention the fuse layer at the level no lower than the highest of the series of patterned conductor layers within the microelectronic fabrication, the fuse layer is provided with enhanced access and actuation.

Similarly, within the present invention the fuse layer is preferably formed of aluminum or an aluminum containing conductor material, while the series of patterned conductor layers is preferably formed of copper or a copper containing conductor material. Within the context of such materials selections, the fuse layer may be readily severed while employing standard fuse severing tooling.

In addition, the present invention also preferably provides that the fuse layer is formed within a microelectronic fabrication simultaneously with at least one of a bond pad layer and an alignment mark layer, such that no additional masking process steps are required when forming the fuse layer in accord with the present invention.

Although the present invention and the preferred embodiment of the present invention provide particular value within the context of fabricating an embedded memory semiconductor integrated circuit microelectronic memory fabrication, the present invention may be employed for fabricating, with enhanced access and actuation of fuse layers formed therein, microelectronic fabrications including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

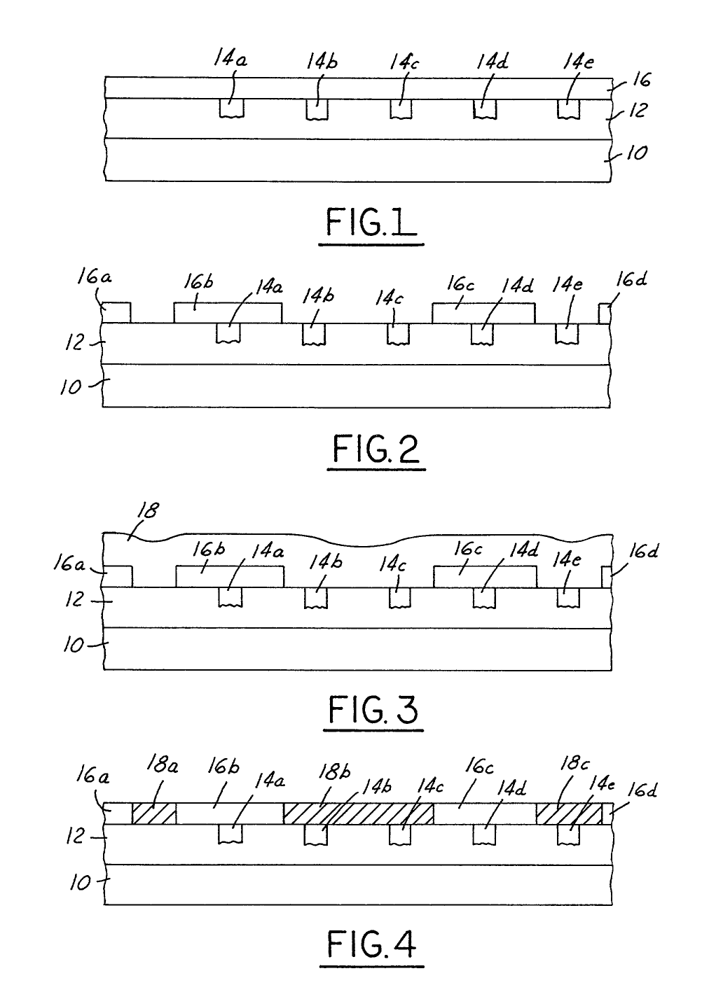

Referring now to FIG. 1 to FIG. 4, there is shown a series of schematic cross-sectional diagrams illustrating the results of progressive stages of fabricating a microelectronic fabrication in accord with a preferred embodiment of the present invention.

Shown in FIG. 1 is a schematic cross-sectional diagram of the microelectronic fabrication at an early stage in its fabrication in accord with the preferred embodiment of the present invention.

Shown in FIG. 1, in a first instance, is a substrate 10 having formed thereover a first dielectric layer 12 which in turn has formed therein a series of patterned first conductor layers 14a, 14b, 14c, 14d and 14e.

Within the preferred embodiment of the present invention with respect to the substrate 10 (which provides a horizontal reference plane with respect to subsequent layers formed thereupon), and although, as noted above, the present invention provides particular value within the context of an embedded memory semiconductor integrated circuit microelectronic memory fabrication, the substrate 10, in additional to consisting of or comprising a semiconductor substrate as employed within a semiconductor integrated circuit microelectronic fabrication, may consist of or comprise a substrate as employed within a microelectronic fabrication selected from the group including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

Although not specifically illustrated within the schematic cross-sectional diagram of FIG. 1, typically and preferably, but not exclusively, when the substrate 10 consists of or comprises a semiconductor substrate as employed within a semiconductor integrated circuit microelectronic fabrication, the substrate 10 has formed therein and/or thereupon microelectronic devices, and in particular semiconductor devices, as are conventional within the microelectronic fabrication within which is employed the substrate 10. Such microelectronic devices may be selected from the group including but not limited to resistors, transistors, diodes and capacitors.

Within the preferred embodiment of the present invention with respect to the first dielectric layer 12, the first dielectric layer 12 may be formed from any of several dielectric materials as are otherwise generally conventional in the art of microelectronic fabrication, such dielectric materials being selected from the group including but not limited to conventional silicon containing dielectric materials (such as but not limited to silicon oxide dielectric materials, silicon nitride dielectric materials and silicon oxynitride dielectric materials), as well as lesser conventional low dielectric constant dielectric materials (such as but not limited to spin-on-glass (SOG) dielectric materials, spin-on-polymer (SOP) dielectric materials, amorphous carbon dielectric materials and fluorinated silicate glass (FSG) dielectric materials). Typically and preferably the dielectric layer 12 is formed as a laminate of from about 1 to about 8 dielectric sub-layers formed employing any of the foregoing dielectric materials, to form the dielectric layer 12 of thickness from about 100,000 to about 200,000 angstroms upon the substrate 10.

Similarly, within the preferred embodiment of the present invention with respect to the series of patterned first conductor layers 14a, 14b, 14c, 14d and 14e, the series of patterned first conductor layers 14a, 14b, 14c, 14d and 14e may also be formed employing conductor materials as are generally conventional in the art of microelectronic fabrication, including but not limited to metal, metal alloy, doped polysilicon (having a dopant concentration of greater than about 1E18 dopant atoms per cubic centimeters) and polycide (doped polysilicon/metal silicide stack) conductor materials, although within the preferred embodiment of the present invention, at least the upper portions of the series of patterned first conductor layers 14a, 14b, 14c, 14d and 14e (and preferably all portions of the series of patterned first conductor layers 14a, 14b, 14c, 14d and 14e) are formed of a copper or copper alloy (of copper content greater than about 90 weight percent) conductor material.

Although also not specifically illustrated within the schematic cross-sectional diagram of FIG. 1, each of the series of patterned first conductor layers 14a, 14b, 14c, 14d and 14e is intended to extend in an interconnected fashion completely through the first dielectric layer 12 such as ultimately to provide connection to a series of microelectronic devices formed within the substrate 10, particularly when the substrate 10 consists of or comprises a semiconductor substrate. Thus, similarly with the dielectric layer 12, the series of patterned first conductor layers 14a, 14b, 14c, 14d and 14e is typically and preferably also formed of a series of patterned conductor sub-layers, generally comprising multiple series of patterned conductor interconnect sub-layers which are further interconnected with patterned conductor stud sub-layers, as is otherwise generally known in the art of microelectronic fabrication.

In addition, and although also not specifically illustrated within the schematic cross-sectional diagram of FIG. 1, each of the patterned first conductor layers 14a, 14b, 14c, 14d and 14e typically and preferably has a linewidth of from about 2.0 to about 4.0 microns within the upper surface of the first dielectric layer 12.

Further, and although also not specifically illustrated within the schematic cross-sectional diagram of FIG. 1, it is intended within the microelectronic fabrication whose schematic cross-sectional diagram is illustrated in FIG. 1 that the patterned conductor layers 14b and 14c should be connected with a fuse and that the patterned conductor layer 14e should ultimately be connected to a bond pad.

Finally, there is also shown within the schematic cross-sectional diagram of FIG. 1 formed upon the first dielectric layer 12 and the series of patterned first conductor layers 14a, 14b, 14c, 14d and 14e a blanket passivation layer 16.

Within the preferred embodiment of the present invention, the blanket passivation layer 16 may be formed employing methods and materials as are conventional in the art of microelectronic fabrication. Typically and preferably, the blanket passivation layer 16 is formed to a thickness of from about 8,000 to about 12,000 angstroms from a silicon nitride passivation dielectric material or a silicon oxynitride passivation dielectric material.

Referring now to FIG. 2, there is shown a schematic cross-sectional diagram illustrating the results of further processing of the microelectronic fabrication whose schematic cross-sectional diagram is illustrated in FIG. 1.

Shown in FIG. 2 is a schematic cross-sectional diagram of a microelectronic fabrication otherwise equivalent to the microelectronic fabrication whose schematic cross-sectional diagram is illustrated in FIG. 1, but wherein the blanket passivation layer 16 has been patterned to form a series of patterned passivation layers 16a, 16b, 16c and 16d which in turn define a series of apertures. Within the present invention, one of the apertures leaves exposed the pair of patterned first conductor layers 14b and 14c which are desired to be connected with the fuse, and another of the apertures leaves exposed the patterned first conductor layer 14e to which is desired to be formed the bond pad.

Within the preferred embodiment of the present invention, the blanket passivation layer 16 may be patterned to form the patterned passivation layers 16a, 16b, 16c and 16d while employing photolithographic patterning methods as are conventional in the art of microelectronic fabrication.

Referring now to FIG. 3, there is shown a schematic cross-sectional diagram illustrating the results of further processing of the microelectronic fabrication whose schematic cross-sectional diagram is illustrated in FIG. 2.

Shown in FIG. 3 is a schematic cross-sectional diagram of a microelectronic fabrication otherwise equivalent to the microelectronic fabrication whose schematic cross-sectional diagram is illustrated in FIG. 2, but wherein there is formed upon exposed portions of the series of patterned passivation layers 16a, 16b, 16c and 16d, the first dielectric layer 12 and the series of patterned first conductor layers 14b, 14c and 14e a blanket aluminum containing conductor layer 18, although other conductor materials may also be employed.

Within the preferred embodiment of the present invention, the blanket aluminum containing conductor layer 18 may be formed employing methods and aluminum containing conductor materials as are conventional in the art of microelectronic fabrication. Typically and preferably, the blanket aluminum containing conductor layer 18 is formed to a thickness of from about 1,000 to about 16,000 angstroms from an aluminum conductor material or an aluminum containing conductor material of aluminum content of greater than about 99.5 weight percent.

Referring now to FIG. 4, there is shown a schematic cross-sectional diagram illustrating the results of further processing of the microelectronic fabrication whose schematic cross-sectional diagram is illustrated in FIG. 3.

Shown in FIG. 4 is a schematic cross-sectional diagram of a microelectronic fabrication otherwise equivalent to the microelectronic fabrication whose schematic cross-sectional diagram is illustrated in FIG. 3, but wherein the blanket aluminum containing conductor layer 18 has been planarized to form a series of patterned planarized aluminum containing conductor layers 18a, 18b and 18c, wherein: (1) the patterned planarized aluminum containing conductor layer 18a forms an alignment mark; (2) the patterned planarized aluminum containing conductor layer 18b forms a fuse bridging the pair of patterned first conductor layers 14b and 14c; and (3) the patterned planarized aluminum containing conductor layer forms a bond pad contacting the patterned first conductor layer 14e. The alignment mark serves an alignment function with respect to the fuse and the bond pad.

As is understood by a person skilled in the art, the microelectronic fabrication whose schematic cross-sectional diagram is illustrated in FIG. 6 may be electrically tested through electrical tester contact with the patterned planarized aluminum containing conductor layer 18c which forms the bond pad, and if needed the patterned planarized aluminum containing conductor layer 18b which forms the fuse layer may be actuated for purposes, for example, of severing within the microelectronic fabrication non-functional circuit elements. Thus, there is formed within the context of the present invention a microelectronic fabrication having formed therein a fuse layer which is readily accessed and actuated since the fuse layer is formed at a level within the microelectronic fabrication no lower than a highest of a series of patterned conductor layers (i.e., the series of patterned first conductor layers 14a, 14b, 14c, 14d and 14e) within the microelectronic fabrication, and preferably upon the highest of the series of patterned conductor layers within the microelectronic fabrication.

As is further understood by a person skilled in the art, by employing within the context of the preferred embodiment of the present invention the series of patterned planarized aluminum containing conductor layers 18a, 18b and 18c which comprise the alignment mark, the fuse layer and the bond pad layer formed of an aluminum containing conductor material, each of those three layers is less susceptible to corrosion and oxidation which may impede the corresponding recognition, severing and bonding with respect to those three layers.

As is understood by a person skilled in the art, the preferred embodiment of the present invention is illustrative of the present invention rather than limiting of the present invention. Revisions and modifications may be made to methods, materials, structures and dimensions through which is fabricated a microelectronic fabrication in accord with the preferred embodiment of the present invention while still providing a microelectronic fabrication in accord with the present invention, and a method for fabrication thereof, further in accord with the accompanying claims.

What is claimed is:

1. A method for fabricating a microelectronic fabrication comprising:
providing a substrate;
forming over the substrate a series of patterned conductor layers separated by a series of dielectric layers; and
forming over the substrate in electrically connected with the series of patterned conductor layers separated by the series of dielectric layers at least one fuse layer, wherein the at least one fuse layer is formed at a level no lower than a highest of the series of patterned conductor layers.

2. The method of claim 1 wherein the microelectronic fabrication is selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

3. The method of claim 1 wherein the at least one fuse layer is formed simultaneously with a bond pad layer within the microelectronic fabrication.

4. The method of claim 1 wherein the at least one fuse layer is formed simultaneously with an alignment mark within the microelectronic fabrication.

5. The method of claim 1 wherein the at least one fuse layer and the highest of the series of patterned conductor layers are formed of different conductor materials.

6. The method of claim 1 wherein the at least one fuse layer is formed of an aluminum containing conductor material and the highest of the series of patterned conductor layers is formed of a copper containing conductor material.

7. A microelectronic fabrication comprising:
a substrate;
a series of patterned conductor layers separated by a series of dielectric layers formed over the substrate; and
at least one fuse layer formed over the substrate and electrically connected with the series of patterned conductor layers separated by the series of dielectric layers, wherein the at least one fuse layer is formed at a level no lower than a highest of the series of patterned conductor layers.

8. The microelectronic fabrication of claim 7 wherein the microelectronic fabrication is selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

9. The microelectronic fabrication of claim 7 wherein the at least one fuse layer is formed at a level equivalent with a bond pad layer within the microelectronic fabrication.

10. The microelectronic fabrication of claim 7 wherein the at least one fuse layer is formed at a level equivalent with an alignment mark within the microelectronic fabrication.

11. The microelectronic fabrication of claim 7 wherein the at least one fuse layer and the highest of the series of patterned conductor layers are formed of different conductor materials.

12. The microelectronic fabrication of claim 7 wherein the at least one fuse layer is formed of an aluminum containing conductor material and the highest of the series of patterned conductor layers is formed of a copper containing conductor material.
